(19) United States
(12) Patent Application Publication
(10) Pub. No.: US 2023/0038806 A1
(43) Pub. Date: Feb. 9, 2023

(54) SEMICONDUCTOR DEVICE

(71) Applicant: DENSO CORPORATION, Kariya-city (JP)

(72) Inventor: Kenji KOUNO, Kariya-city (JP)

(21) Appl. No.: 17/969,023

(22) Filed: Oct. 19, 2022

Related U.S. Application Data
(63) Continuation of application No. PCT/JP2021/016068, filed on Apr. 20, 2021.

(30) Foreign Application Priority Data
Apr. 22, 2020 (JP) 2020-076334

(51) Int. Cl. H01L 29/10; H01L 29/16; H01L 29/06; H01L 29/808; H01L 27/06; H01L 29/78; H03K 17/687; H02M 1/08

(52) U.S. Cl. CPC H01L 29/1095; H01L 29/1608; H01L 29/0623; H01L 29/8083; H01L 27/0629; H01L 29/0634; H01L 29/7811; H01L 29/7813; H03K 17/6871; H02M 1/08; H02P 27/06

(57) ABSTRACT

A semiconductor device includes a MOSFET including a drift layer, a channel layer, a trench gate structure, a source layer, a drain layer, a source electrode, and a drain electrode. The trench gate structure includes a trench penetrating the channel layer and protruding into the drift layer, a gate insulating film disposed on a wall surface of the trench, and a gate electrode disposed on the gate insulating film. A portion of the trench protruding into the drift layer is entirely covered with a well layer, and the well layer is connected to the channel layer.

### CROSS REFERENCE TO RELATED APPLICATIONS

The present application is a continuation application of International Patent Application No. PCT/JP2021/016068 filed on Apr. 20, 2021, which designated the U.S. and claims the benefit of priority from Japanese Patent Application No. 2020-076334 filed on Apr. 22, 2020. The entire disclosures of all of the above applications are incorporated herein by reference.

### TECHNICAL FIELD

The present disclosure relates to a semiconductor device including a metal oxide semiconductor field effect transistor (MOSFET) having a trench gate structure.

### BACKGROUND

Conventionally, there has been proposed a semiconductor device including a MOSFET having a trench gate structure.

### SUMMARY

The present disclosure provides a semiconductor device including a MOSFET. The MOSFET includes a drift layer, a channel layer, a trench gate structure, a source layer, a drain layer, a source electrode, and a drain electrode. The trench gate structure includes a trench penetrating the channel layer and protruding into the drift layer, a gate insulating film disposed on a wall surface of the trench, and a gate electrode disposed on the gate insulating film. A portion of the trench protruding into the drift layer is entirely covered with a well layer, and the well layer is connected to the channel layer.

### BRIEF DESCRIPTION OF DRAWINGS

Objects, features and advantages of the present disclosure will become apparent from the following detailed description made with reference to the accompanying drawings. In the drawings:

FIG. 1 is a circuit diagram of a semiconductor device according to a first embodiment;

FIG. 2 is a plan view of a first semiconductor chip in which a junction field effect transistor (JFET) is formed;

FIG. 3 is an enlarged view of a region III in FIG. 2;

FIG. 4 is a cross-sectional view taken along a line IV-IV shown in FIG. 3;

FIG. 5 is a cross-sectional view taken along a line V-V shown in FIG. 3;

FIG. 6 is a cross-sectional view taken along a line VI-VI shown in FIG. 3;

FIG. 7 is a plan view of a second semiconductor chip in which a MOSFET is formed;

FIG. 8 is a cross-sectional view taken along a line VIII-VIII in FIG. 7;

FIG. 9 is a cross-sectional view taken along a line IX-IX in FIG. 7;

FIG. 10 is a diagram showing simulation results regarding the relationship between an area density ratio, an on-voltage, and a recovery loss;

FIG. 11 is a cross-sectional view of a second semiconductor chip according to a second embodiment;

FIG. 12 is a circuit diagram of a semiconductor device according to a third embodiment;

FIG. 13 is a circuit diagram of an inverter configured using the semiconductor device shown in FIG. 12; and

FIG. 14 is a circuit diagram of a U layer in FIG. 13.

### DETAILED DESCRIPTION

A semiconductor device according to a related art includes a MOSFET formed using a semiconductor substrate that includes an N⁻ type drift layer. A channel layer is formed on one surface of the semiconductor substrate, and multiple trenches are formed to penetrate the channel layer and protrude into the drift layer. Each of the trenches extend in one direction in a planar direction of the semiconductor substrate as a longitudinal direction. Then, a gate insulating film and a gate electrode are formed in this order in each of the trenches to form a trench gate structure. In a surface portion of the channel layer, N⁺ type source regions are formed so as to be in contact with the trenches, respectively. On the other surface of the semiconductor substrate, an N⁺ type drain layer is formed.

In the above-described MOSFET, a parasitic diode (hereinafter also simply referred to as a diode) is formed by the channel layer, the drift layer, and the drain layer. During recovery operation of the diode, if electric field concentration occurs at bottoms of the trenches, holes are generated by dynamic avalanche, and a recovery loss is likely to increase. Therefore, for example, a P type impurity layer may be disposed so as to partially cover portions of the trenches that protrude into the drift layer.

However, even in the above-described semiconductor device, the recovery loss may not be sufficiently reduced.

A semiconductor device according to an aspect of the present disclosure includes a MOSFET including a drift layer, a channel layer, a trench gate structure, a source layer, a drain layer, a source electrode, and a drain electrode. The drift layer has a first conductivity type. The channel layer has a second conductivity type and is disposed on the drift layer. The trench gate structure includes a trench penetrating the channel layer and protruding into the drift layer, a gate insulating film disposed on a wall surface of the trench, and a gate electrode disposed on the gate insulating film. The source layer is disposed in a surface layer portion of the channel layer so as to be in contact with the trench. The source layer has the first conductivity type and has an impurity concentration higher than an impurity concentration of the drift layer. The drain layer has the first conductivity type and is disposed on a side of drift layer opposite from the channel layer. The source electrode is electrically connected to the channel layer and the source layer. The drain electrode is electrically connected to the drain layer. A portion of the trench protruding into the drift layer is entirely covered with a well layer of the second conductivity type. The well layer is connected to the channel layer.

In the above-described semiconductor device, the portion of the trench protruding into the drift layer is entirely covered with the well layer. Therefore, it is possible to suppress the occurrence of electric field concentration at a bottom of the trench and suppress the generation of holes by dynamic avalanche. Therefore, a recovery loss can be reduced.

The following describes embodiments of the present disclosure with reference to the drawings. In the following embodiments, the same or equivalent parts are denoted by the same reference numerals for description.

### First Embodiment

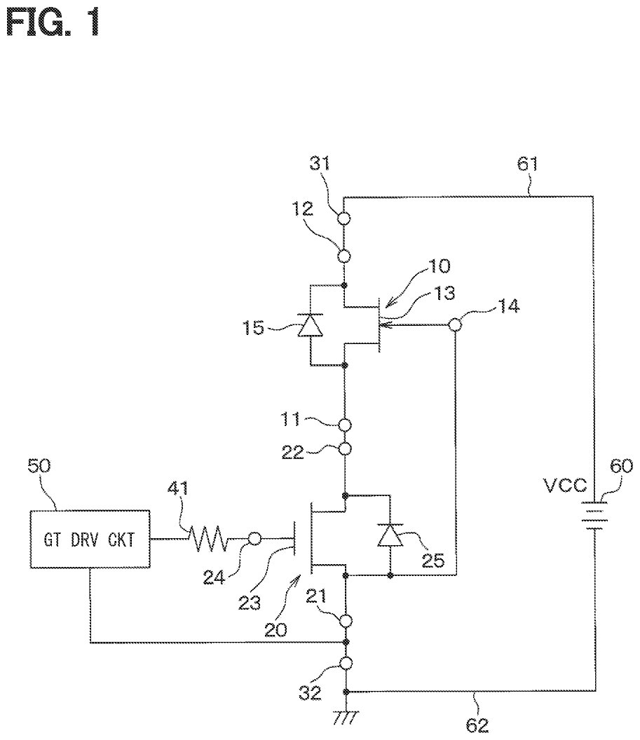

A first embodiment will be described with reference to the drawings. First, a circuit configuration of a semiconductor device according to the present embodiment will be described. As shown in FIG. 1, the semiconductor device of the present embodiment includes a normally-on junction field effect transistor (JFET) 10 and a normally-off MOSFET 20. The JFET 10 and the MOSFET 20 are cascode-connected. In the present embodiment, each of the JFET 10 and the MOSFET 20 is an N channel type device.

The JFET 10 includes a source electrode 11, a drain electrode 12, and a gate layer (that is, a gate electrode) 13. The MOSFET 20 includes a source electrode 21, a drain electrode 22, and a gate electrode 23.

In the JFET 10 and the MOSFET 20, the source electrode 11 of the JFET 10 and the drain electrode 22 of the MOSFET 20 are electrically connected. The drain electrode 12 of the JFET 10 is connected to a first terminal 31, and the source electrode 21 of the MOSFET 20 is connected to a second terminal 32.

The gate electrode 23 of the MOSFET 20 is connected to a gate drive circuit (GT DRV CKT) 50 via a gate pad 24 and an adjustment resistor 41. The gate layer 13 of the JFET 10 is electrically connected to the source electrode 21 of the MOSFET 20 via a gate pad 14.

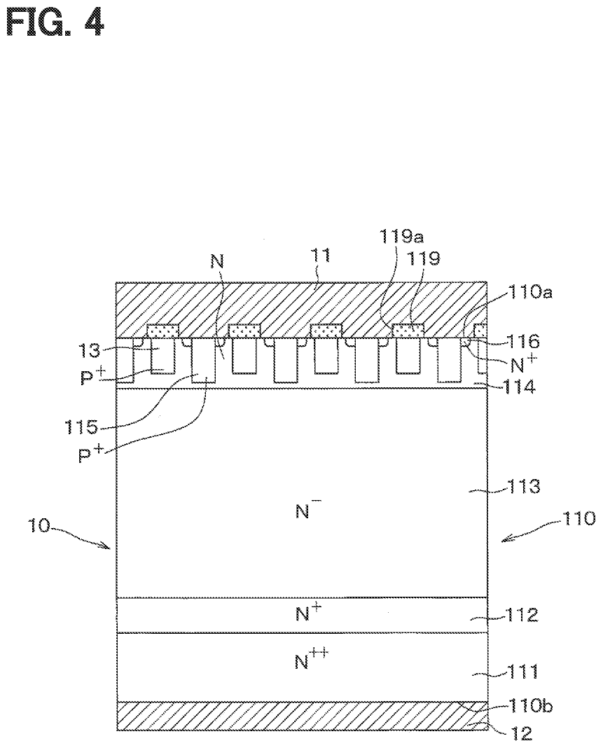

In the present embodiment, a diode 15 is connected between the drain electrode 12 and the source electrode 11 of the JFET 10. Although the details will be described later, in the present embodiment, the JFET 10 has a P⁺ type body layer 115 formed in an N type channel layer 114 as shown in FIG. 4. The diode 15 includes the body layer 115. The diode 15 has a cathode electrically connected to the drain electrode 12 and an anode electrically connected to the source electrode 11.

A diode 25 is connected between the drain electrode 22 and the source electrode 21 of the MOSFET 20. The diode 25 is a parasitic diode formed on the configuration of the MOSFET 20, and has a cathode electrically connected to the drain electrode 22 and an anode electrically connected to the source electrode 21.

The circuit configuration of the semiconductor device according to the present embodiment is described above. In the semiconductor device, the first terminal 31 is connected to a power supply line 61 to which a voltage Vcc is applied from a power supply 60, and the second terminal 32 is connected to a ground line 62.

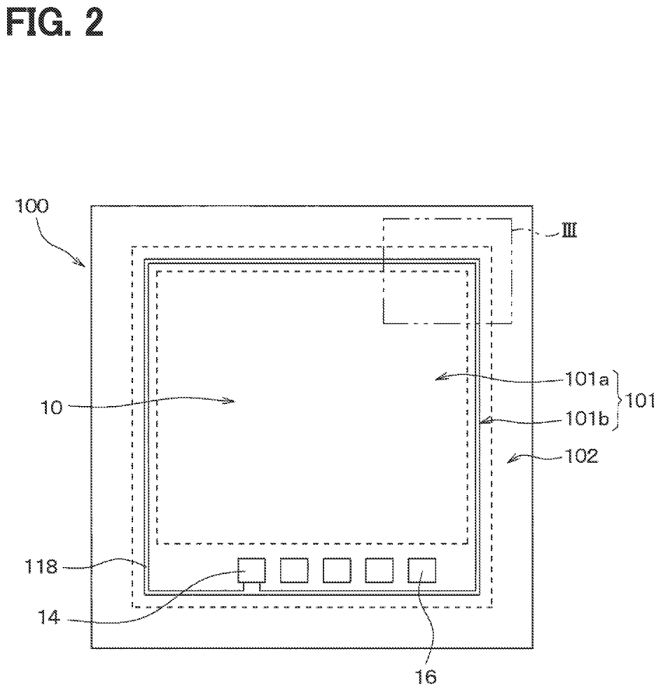

Next, specific configurations of the JFET 10 and the MOSFET 20 will be described. First, the configuration of the JFET 10 will be described. The JFET 10 is formed in a first semiconductor chip 100, as shown in FIG. 2.

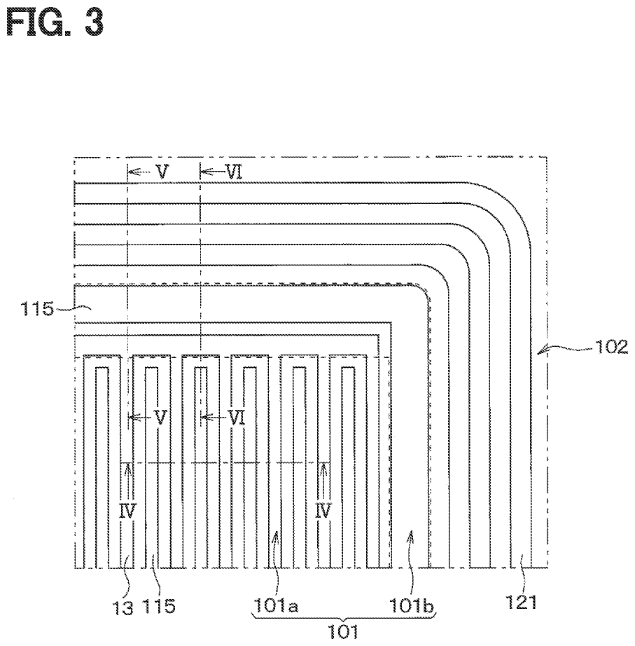

As shown in FIG. 2 and FIG. 3, the first semiconductor chip 100 has a rectangular plane shape, and has a cell region 101 and an outer peripheral region 102 surrounding the cell region 101. The cell region 101 has an inner cell region 101a and an outer cell region 101b surrounding the inner cell region 101a. The JFET 10 is formed in the cell region 101.

Specifically, as shown in FIGS. 4 to 6, the first semiconductor chip 100 includes a semiconductor substrate 110 having a drain layer 111 made of an N⁺⁺ type silicon carbide (hereinafter referred to as SiC) substrate. Then, an N⁺ type buffer layer 112 having an impurity concentration lower than that of the drain layer 111 is disposed on the drain layer 111, and an N⁻ type drift layer 113 having an impurity concentration lower than that of the buffer layer 112 is disposed on the buffer layer 112. The buffer layer 112 and the drift layer 113 are formed, for example, by growing an epitaxial film made of SiC on the SiC substrate constituting the drain layer 111.

In the cell region 101, the channel layer 114, the gate layer 13, the body layer 115, and a source layer 116 are formed to a portion close to one surface 110a of the semiconductor substrate 110. Specifically, in the cell region 101, the N type channel layer 114 having a higher impurity concentration than the drift layer 113 is disposed on the drift layer 113. The channel layer 114 is formed by growing, for example, an epitaxial film of SiC. The one surface 110a of the semiconductor substrate 110 includes a surface of the channel layer 114.

In the channel layer 114, the P⁺ type gate layer 13 and the P⁺ type body layer 115 having a higher impurity concentration than the channel layer 114 are formed. In the present embodiment, the gate layer 13 and the body layer 115 have the same impurity concentration and are formed in a depth direction from the one surface 110a of the semiconductor substrate 110 (that is, the surface of the channel layer 114). However, in the present embodiment, the body layer 115 is formed deeper than the gate layer 13. In other words, the body layer 115 protrudes toward the drain layer 111 more than the gate layer 13.

In addition, the gate layer 13 and the body layer 115 extend along a first direction in a planar direction of the semiconductor substrate 110, and are alternately arranged in a second direction that is included in the planar direction and is orthogonal to the first direction. In other words, in FIG. 4, the gate layer 13 and the body layer 115 extend along a direction perpendicular to a paper plane and are alternately arranged along a horizontal direction of the paper plane while being separated from each other. The depth direction of the semiconductor substrate 110 may also be referred to as a stacking direction of the drain layer 111, the drift layer 113 and the channel layer 114. The gate layer 13 and the body layer 115 are formed by, for example, ion implantation or growing a buried epitaxial film of SiC.

In the present embodiment, as shown in FIGS. 3, 5 and 6, the gate layer 13 extends from the inner cell region 101a to the outer cell region 101b. The gate layer 13 has an annular structure by bending and connecting both ends in the extending direction located in the outer cell region 101b, and the annular structures are connected to each other. For this reason, the body layer 115 in FIG. 4 is disposed in a portion on an inner side of the gate layer 13 having the annular structure.

In the present embodiment, as shown in FIGS. 3, 5, and 6, the body layer 115 is also formed in the outer cell region 101 and is connected to one of guard rings 121 formed in the outer peripheral region 102.

As shown in FIG. 4, the N⁺ type source layer 116 having a higher impurity concentration than the channel layer 114 is formed in a surface layer portion of the channel layer 114 so as to be in contact with the body layer 115. The source layer 116 is formed by, for example, ion implantation.

As shown in FIGS. 3, 5 and 6, above the semiconductor substrate 110, the gate pad 14 and a gate wiring 118 electrically connecting the gate pad 14 and the gate layer 13 are formed in the outer cell region 101b. Although not shown, the first semiconductor chip 100 also has a temperature sensor, a current sensor, and the like. Pads 16 electrically connected to these various sensors and wirings (not shown) are also formed in the outer cell region 101b.

As shown in FIGS. 4 to 6, an interlayer insulating film 119 is formed on the one surface 110a of the semiconductor substrate 110 so as to cover the gate wiring 118. The interlayer insulating film 119 is formed in the cell region 101 and the outer peripheral region 102. The interlayer insulating film 119 has contact holes 119a in the cell region 101 to expose the channel layer 114, the body layer 115, and the source layer 116. A source electrode 11 electrically connected to the source layer 116 and the body layer 115 through the contact holes 119a is formed on the interlayer insulating film 119.

A drain electrode 12 that is electrically connected to the drain layer 111 is formed on the other surface 110b of the semiconductor substrate 110.

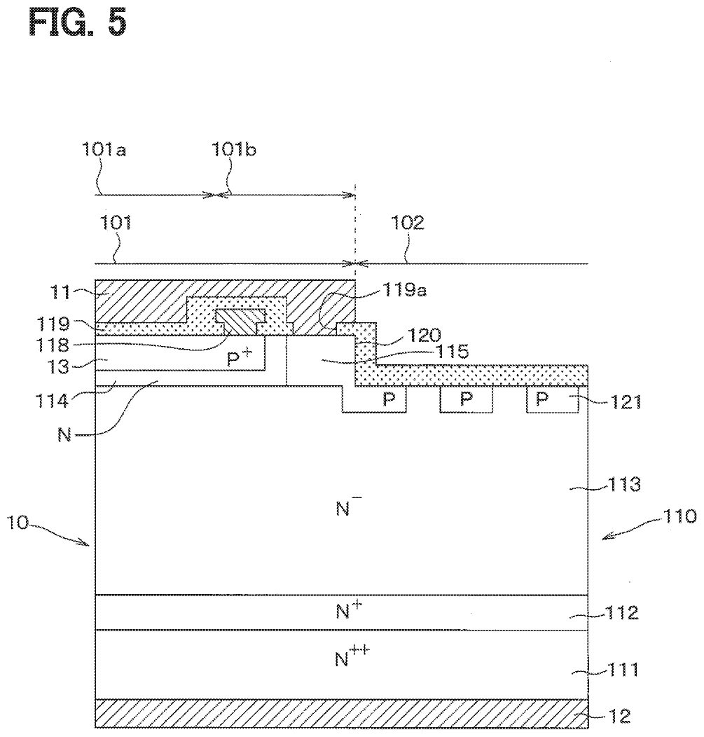

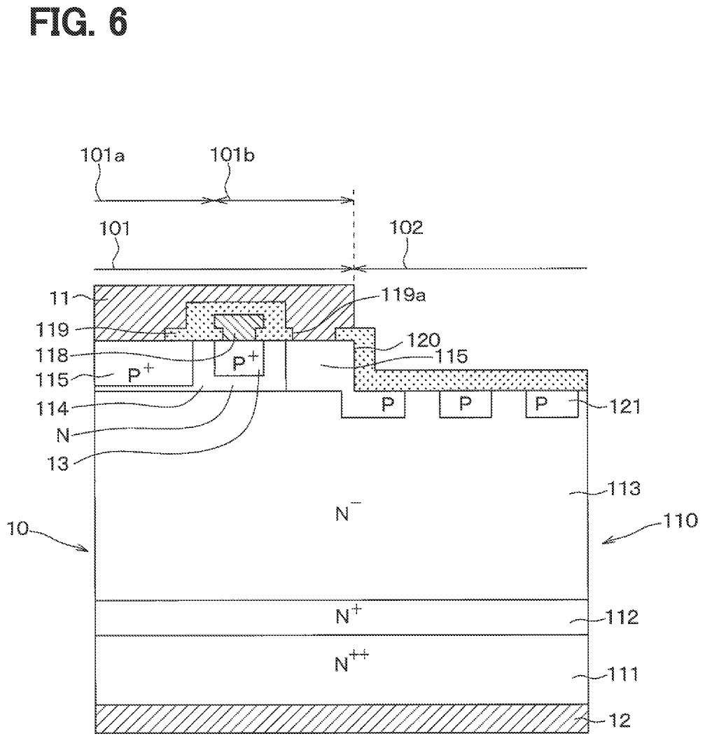

As shown in FIGS. 5 and 6, the outer peripheral region 102 has a mesa structure having a recessed portion 120. The recessed portion 120 is formed by removing a portion corresponding to the channel layer 114 in the cell region 101. The guard rings 121 having a multiple ring structure surrounding the cell region 101 are formed in the outer peripheral region 102. In the present embodiment, one of the guard rings 121 closest to the cell region 101 is electrically connected to the body layer 115 formed in the outer cell region 101b. Alternatively, the one of the guard rings 121 closest to the cell region 101 may not be electrically connected to the body layer 115.

The above is the configuration of the first semiconductor chip 100 of the present embodiment. In the first semiconductor chip 100 of the present embodiment, the N− type, the N type, the N⁺ type, and the N⁺⁺ type correspond to a first conductivity type, and the P type and the P⁺ type correspond to a second conductivity type. In the present embodiment, the semiconductor substrate 110 includes the drain layer 111, the buffer layer 112, the drift layer 113, the channel layer 114, the body layer 115, the source layer 116, and the gate layer 13, as described above. Further, in the present embodiment, as described above, the drain layer 111 is formed of a SiC substrate, and the buffer layer 112, the drift layer 113, the channel layer 114 and the like are formed by growing an epitaxial film made of SiC. Therefore, it can be said that the first semiconductor chip 100 of the present embodiment is a SiC semiconductor device. In the present embodiment, the P type body layer 115 is formed in the first semiconductor chip 100. The diode 15 in FIG. 1 is formed due to body layer 115.

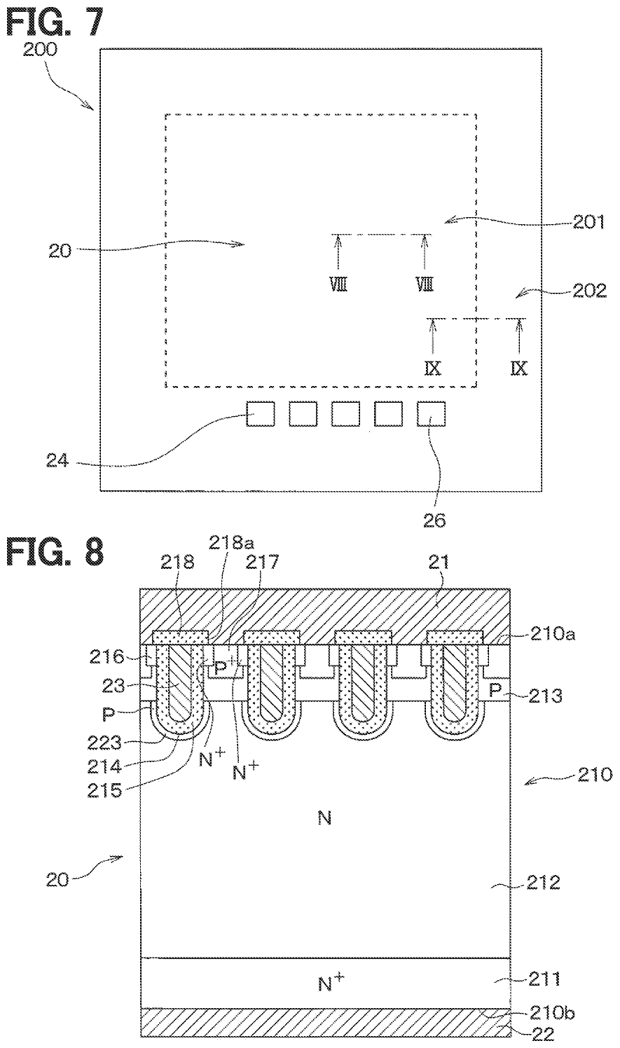

Next, the configuration of the MOSFET 20 will be described. The MOSFET 20 is formed on a second semiconductor chip 200, as shown in FIG. 7.

The second semiconductor chip 200 has a rectangular plane shape, and has a cell region 201 and an outer peripheral region 202 surrounding the cell region 201. The MOSFET 20 is formed in the cell region 201.

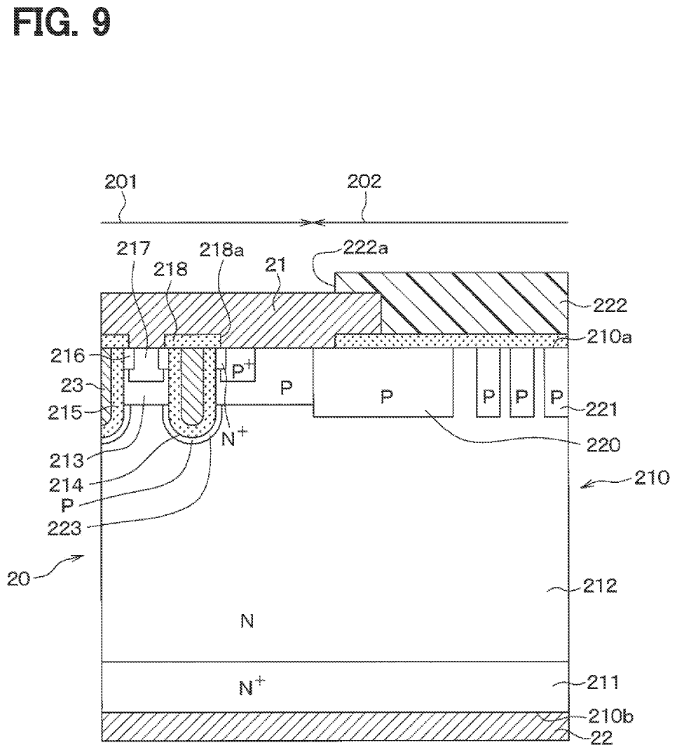

Specifically, as shown in FIG. 8 and FIG. 9, the second semiconductor chip 200 includes a semiconductor substrate 210 having a drain layer 211 made of an N⁺ type silicon carbide (hereinafter referred to as SiC) substrate. An N type drift layer 212 having a lower impurity concentration than the drain layer 211 is disposed on the drain layer 211. In the cell region 201, a P type channel layer 213 having a higher impurity concentration than the drift layer 212 is disposed on the drift layer 212.

In addition, a plurality of trenches 214 are formed in the semiconductor substrate 210 so as to penetrate the channel layer 213 and protrude into the drift layer 212, and the channel layer 213 is separated into a plurality of portions by the trenches 214. In this embodiment, the plurality of trenches 214 are formed in stripes at equal intervals along one direction in a planar direction of one surface 210a of the semiconductor substrate 210 (that is, a direction perpendicular to a paper plane of FIG. 8). Note that the plurality of trenches 214 may have an annular structure by bending tip portions thereof.

Each of the trenches 214 is embedded with a gate insulating film 215 formed to cover an inner wall surface of each of the trenches 214, and a gate electrode 23 formed on the gate insulating film 215. The gate electrode 23 is formed of polysilicon or the like. Accordingly, the trench gate structure is formed.

In the channel layer 213, an N⁺ type source layer 216 and a P⁺ type contact layer 217 are formed so as to be sandwiched between the source layer 216. The source layer 216 is configured to have a higher impurity concentration than the drift layer 212, is terminated in the channel layer 213, and is in contact with a side wall of the trench 214. The contact layer 217 has a higher impurity concentration than the channel layer 213 and is formed so as to terminate in the channel layer 213, similarly to the source layer 216.

To be more specific, the source layer 216 is extended in a rod shape to be in contact with the side wall of the trench 214 along the longitudinal direction of the trench 214 in a region between adjacent two of the trenches 214, and terminated inside a tip of the trench 214. The contact layer 217 is sandwiched between two source layers 216 and extends in a rod shape along the longitudinal direction of the trench 214 (that is, the source layer 216). Note that the contact layer 217 of the present embodiment is formed deeper than the source layer 216 with respect to the one surface 210a of the semiconductor substrate 210.

An interlayer insulating film 218 is formed on the channel layer 213 (that is, one surface 210a of the semiconductor substrate 210). The interlayer insulating film 218 is also formed in the outer peripheral region 202 as shown in FIG. 9. In the interlayer insulating film 218, a contact hole 218a exposing a part of the source layer 216 and the contact layer 217 is formed. On the interlayer insulating film 218, the source electrode 21 electrically connected to the source layer 216 and the contact layer 217 through the contact hole 218a is formed.

A drain electrode 22 that is electrically connected to the drain layer 211 is formed on the other surface 210b of the semiconductor substrate 210.

In the outer peripheral region 202, as shown in FIG. 7, the gate pads 24, gate wirings (not shown), and the like are formed. The gate wirings are electrically connected to the gate electrodes 23 respectively in a cross section different from that in FIGS. 8 and 9. Although not shown, the second semiconductor chip 200 also has a temperature sensor, a current sensor, and the like. In the outer peripheral region 202, pads and wirings (not shown) electrically connected to various sensors are also formed.

Furthermore, in the outer peripheral region 202, a P type deep layer 220 is formed in an inner portion close to the cell region 201, and a plurality of P type guard rings 221 having a multi-ring structure is formed in an outer portion that is outer than the deep layer 220. The deep layer 220 of the present embodiment is connected to the channel layer 213 and is formed deeper than the channel layer 213. A protective film 222 covering the interlayer insulating film 218 is formed in the outer peripheral region 202, and the protective film 222 has an opening 222a to expose the source electrode 21. Since the MOSFET 20 has the configuration as described above, the diode 25 shown in FIG. 1 is formed by the channel layer 213, the drift layer 212, and the drain layer 211.

In the MOSFET 20 of the present embodiment, a P type well layer 223 is formed along the wall surface of the trench 214 in the entire area of a portion of the drift layer 212 in contact with the trench 214. In other words, a portion of trench 214 protruding into drift layer 212 is entirely covered with well layer 223. Note that the well layer 223 is formed so as to be connected to the channel layer 213.

Accordingly, during the recovery of the diode 25 in the MOSFET 20, the well layer 223 can suppress the occurrence of electric field concentration at the bottom of the trench 214, and the generation of holes by dynamic avalanche can be suppressed. Therefore, a recovery loss can be reduced.

The well layer 223 can be formed by implanting impurities such as boron into the wall surface of the trench 214 after forming the trench 214 and before forming the gate insulating film 215, the gate electrode 23, and the like.

In the MOSFET 20, an inversion layer functioning as a channel is formed in a portion of the channel layer 213 and the well layer 223 that is in contact with the trench 214 by applying a predetermined gate voltage to the gate electrode 23. In this case, if an impurity area density of the well layer 223 is too high, a channel may not be properly formed in the well layer 223 and an on-voltage may increase.

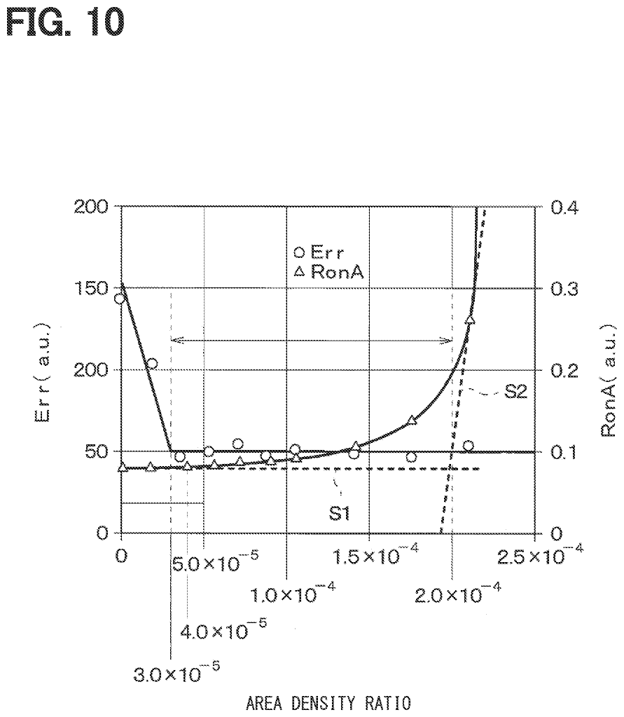

Thus, the inventor further investigated the relationship between an area density ratio of the impurity area density of the well layer 223 to the impurity area density of the drift layer 212 (hereinafter simply referred to as the area density ratio), the on-voltage, and the recovery loss, and the results shown in FIG. 10 were obtained. In FIG. 10, Err indicates the recovery loss, and RonA indicates the on-voltage. Further, the area density ratio is the impurity area density of the well layer 223/the impurity area density of the drift layer 212.

As shown in FIG. 10, it is confirmed that the recovery loss is reduced by forming the well layer 223. Specifically, it is confirmed that the recovery loss sharply drops until the area density ratio reaches 3.0×10⁻⁵. It is also confirmed that the recovery loss becomes almost constant when the area density ratio is 3.0×10⁻⁵ or more.

On the other hand, it is confirmed that the on-voltage is almost constant up to an area density ratio of 4.0×10⁻⁵. It is also confirmed that the on-state voltage gradually increases when the area density ratio exceeds 4.0×10⁻⁵. In the on-voltage, an intersection of a tangent line 51 at a portion where the inclination is the smallest and a tangent line S2 at a portion where the inclination is the largest is a portion where the area density ratio is 2.0×10⁻⁴. Therefore, it can be said that the on-voltage sharply increases when the area density ratio exceeds 2.0×10⁻⁴.

Therefore, in the present embodiment, the area density ratio is set in a range from 3.0×10⁻⁵ to 2.0×10⁻⁴ inclusive. Thereby, it is possible to suppress an increase in the on-voltage while reducing the recovery loss. The area density ratio may be set in a range from 3.0×10⁻⁵ to 4.0×10⁻⁵ inclusive. Thereby, it is possible to sufficiently suppress an increase in the on-voltage while reducing the recovery loss.

The above is the configuration of the second semiconductor chip 200 of the present embodiment. In the second semiconductor chip 200 of the present embodiment, the N type, N⁻ type, the N⁺ type, and the N⁺⁺ type correspond to a first conductivity type, and the P type and the P⁺ type correspond to a second conductivity type. In the present embodiment, the semiconductor substrate 210 includes the drain layer 211, the drift layer 212, the channel layer 213, the source layer 216, the contact layer 217, and the well layer 223 as described above. Furthermore, in the present embodiment, the second semiconductor chip 200 is configured using the Si substrate as described above. Therefore, it can be said that the second semiconductor chip 200 is a Si semiconductor device.

In the semiconductor device of the present embodiment, although not shown, the JFET 10 formed in the first semiconductor chip 100 and the MOSFET 20 formed in the second semiconductor chip 200 are electrically connected so as to be cascode-connected.

Next, the basic operation of the above semiconductor device will be described. Since the semiconductor device of the present embodiment has the MOSFET 20 that is normally-off, the semiconductor device operates as a normally-off device as a whole.

First, in order to turn on the semiconductor device by a switching-on operation, a gate voltage equal to or higher than a threshold voltage is applied from the gate drive circuit 50 to the gate electrode 23 of the MOSFET 20. As a result, the normally-off type MOSFET 20 turns on. In the JFET 10, the gate layer 13 is connected to the second terminal 32. For this reason, the normally-on type JFET 10 turns on because the potential difference between the gate layer 13 and the source electrode 11 is almost zero. Therefore, a current flows between the first terminal 31 and the second terminal 32, and the semiconductor device finally turns on.

Next, in order to turn off the semiconductor device by a switching-off operation, the gate voltage applied to the gate electrode 23 of the MOSFET 20 is made smaller than the threshold voltage (for example, set to 0 V). As a result, the normally-off type MOSFET 20 turns off. Further, when the MOSFET 20 turns off, the voltage of the drain electrode 22 of the MOSFET 20 and the voltage of the source electrode 11 of the JFET 10 connected thereto increases, and an electric potential is generated between the gate layer 13 of the JFET 10 connected to the second terminal 32 and the source electrode 11. When the potential difference between the source electrode 11 and the gate layer 13 reaches the threshold, the channel disappears and the JFET 10 turns off. As a result, no current flows between the first terminal 31 and the second terminal 32, and the semiconductor device finally turns off.

According to the present embodiment described above, the MOSFET 20 is in a state where the entire region of the portion of the trench 214 protruding into the drift layer 212 is covered with the well layer 223. Therefore, it is possible to suppress the occurrence of electric field concentration at the bottom of the trench 214 and suppress the generation of holes by dynamic avalanche. Therefore, the recovery loss can be reduced.

It is preferable that the MOSFET 20 has the area density ratio in the range from 3.0×10⁻⁵ to 2.0×10⁻⁴ inclusive. In this case, it is possible to suppress an increase in the on-voltage while reducing the recovery loss. It is more preferable that the area density ratio is set in the range from 3.0×10⁻⁵ to 4.0×10⁻⁵ inclusive. In this case, it is possible to sufficiently suppress an increase in the on-voltage while reducing the recovery loss.

In the JFET 10 of the present embodiment, the body layer 115 is deeper than the gate layer 13. For this reason, the electric field strength tends to be higher on the bottom side of the body layer 115 than on the bottom side of the gate layer 13. Therefore, when a surge occurs, a breakdown is likely to occur in the region on the bottom side of the body layer 115, and the surge current easily flows into the body layer 115. As a result, it is possible to suppress a breakdown of the semiconductor device due to fusing of the gate wiring 118, and to improve surge resistance.

### Second Embodiment

A second embodiment will be described. The present embodiment is different from the first embodiment in that a drift layer 212 has a superjunction (hereinafter also simply referred to as SJ) structure. The other configurations are the same as those of the first embodiment, and therefore a description of the same configurations will be omitted below.

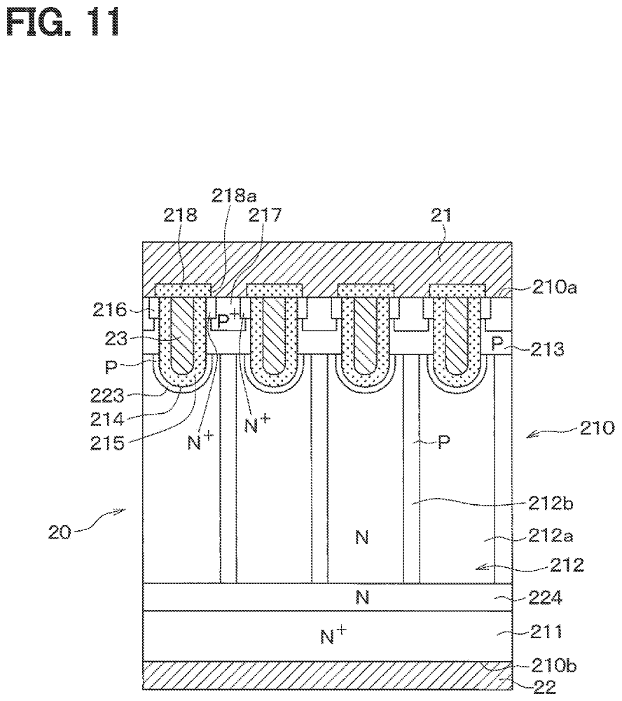

In the present embodiment, as shown in FIG. 11, an N type buffer layer 224 is formed on the drain layer 211. Then, N type column regions 212a and P type column regions 212b as the drift layer 212 are formed on the buffer layer 224 so as to form the SJ structure. In the present embodiment, the N type column regions 212a and the P type column regions 212b extend in one direction parallel to the planar direction of the semiconductor substrate 210 (that is, the direction perpendicular to a paper plane of FIG. 11). In addition, the N type column regions 212a and the P type column regions 212b are repeatedly arranged in a direction perpendicular to the one direction (that is, the horizontal direction of the paper plane of FIG. 11). More specifically, the N type column regions 212a and the P type column regions 212b are formed along the extending direction of the trenches 214 and are repeatedly arranged along the arrangement direction of the trenches 214. The P type column regions 212b are connected to the channel layer 213.

As described above, the first embodiment can also be applied to a semiconductor device having a SJ structure.

### Third Embodiment

A third embodiment will be described. In the present embodiment, an inverter is formed using the semiconductor device of the first embodiment. The other configurations are the same as those of the first embodiment, and therefore a description of the same configurations will be omitted below.

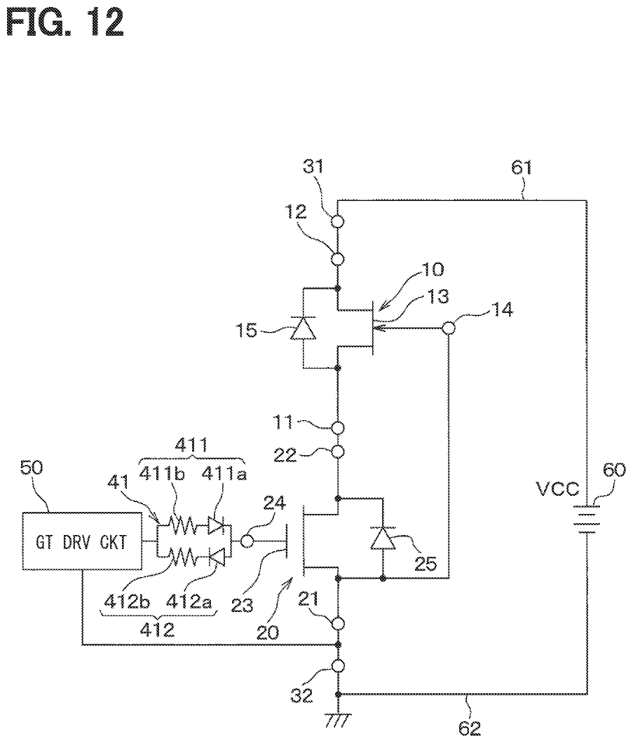

In the present embodiment, as shown in FIG. 12, the adjustment resistor 41 has the following configuration. The adjustment resistor 41 includes a first resistor circuit 411 in which a first diode 411a and a first resistor 411b are connected in series, and a second resistor circuit 412 in which a second diode 412a and a second resistor 412b are connected in series. The first resistor circuit 411 and the second resistor circuit 412 are arranged in parallel such that a cathode of the first diode 411a and an anode of the second diode 412a are connected to the gate electrode 23 of the MOSFET 20.

In the present embodiment, the gate electrode 23 of the MOSFET 20 and the gate drive circuit 50 are connected via the adjustment resistor 41 as described above. Therefore, the switching speed of the MOSFET 20 is adjusted by different resistance circuits between a case of the switching-on operation and a case of the switching-off operation.

Specifically, the gate electrode 23 of the MOSFET 20 is connected to the gate drive circuit 50 via the first resistance circuit 411 when the switching-on operation is performed. That is, the first resistance circuit 411 functions as a speed adjustment resistor for switching-on operation of the MOSFET 20. The gate electrode 23 of the MOSFET 20 is connected to the gate drive circuit 50 via the second resistance circuit 412 when the switching-off operation is performed. That is, the second resistance circuit 412 functions as a speed adjustment resistor for switching-off operation of the MOSFET 20. Therefore, the switching speed of the MOSFET 20 can be appropriately adjusted by adjusting the resistance values of the resistance circuits 411 and 412.

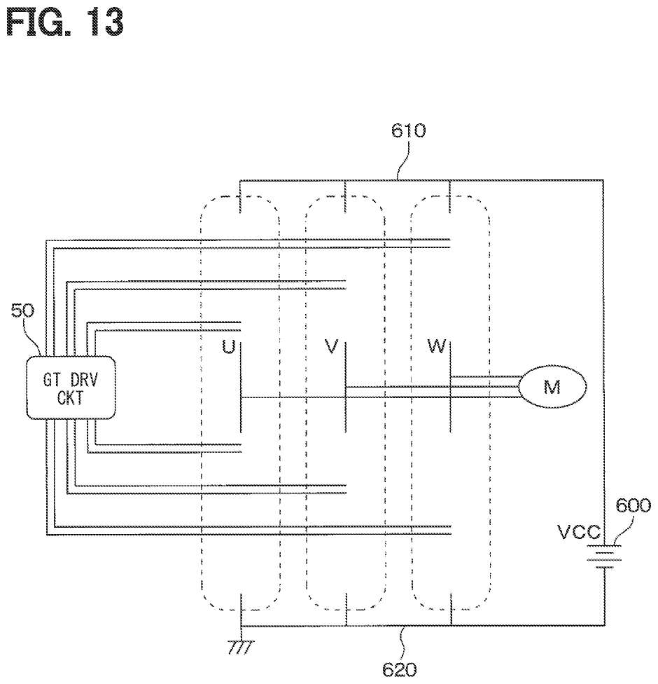

The configuration of the semiconductor device according to the present embodiment has been described above. The semiconductor device can be used as a switching element of an inverter circuit that drives a three-phase motor, for example, as shown in FIG. 13.

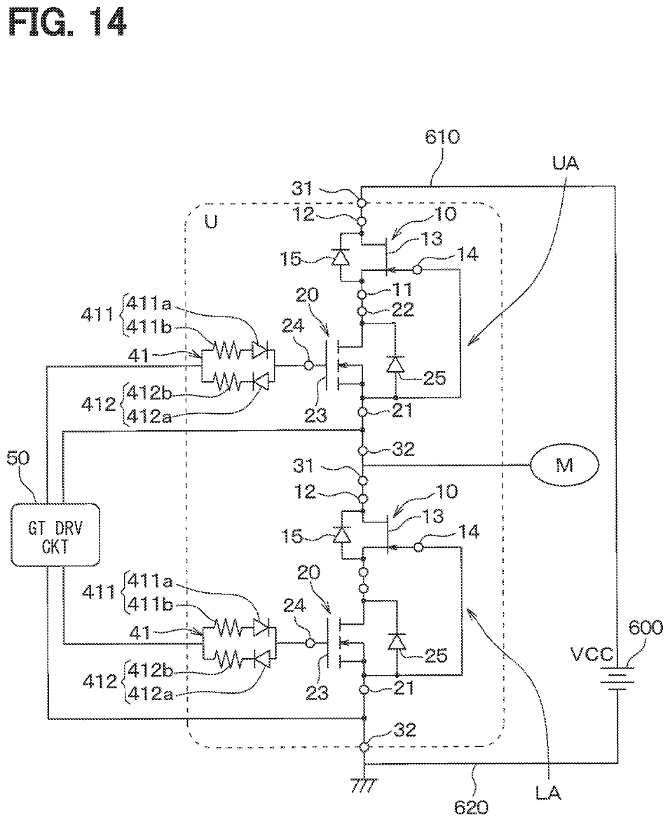

That is, as shown in FIG. 13, the inverter has three circuits of U-phase, V-phase, and W-phase between a power supply line 610 to which a voltage Vcc from a power supply 600 is applied and a ground line 620 connected to the ground. Each layer is connected to the gate drive circuit 50 and the three-phase motor M. Hereinafter, the detailed configuration of the U layer will be described with reference to FIG. 14. Note that the detailed configuration of the V layer and the W layer is the same as that of the U layer, and is omitted to explain.

As shown in FIG. 14, the U layer is configured to include two semiconductor devices shown in FIG. 12. In the U layer, the drain electrode 12 of the JFET 10 in an upper arm UA is connected to the power supply line 610 via the first terminal 31. In the U layer, the source electrode 21 of the MOSFET 20 in a lower arm LA is connected to the ground line 620 via the second terminal 32. In addition, the source electrode 21 of the MOSFET 20 in the upper arm UA is electrically connected to the drain electrode 12 of the JFET 10 in the lower arm LA. That is, the second terminal 32 of the upper arm UA is electrically connected to the first terminal 31 of the lower arm LA. The three-phase motor M is connected between the second terminal 32 of the upper arm UA and the first terminal 31 of the lower arm LA. The gate electrodes 23 of the MOSFETs 20 in the upper arm UA and the lower arm LA are connected to the gate drive circuit 50.

As described above, the semiconductor device of the present embodiment may also be used as the switching element of the inverter.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, in each of the above embodiments, the first conductivity type may be P type and the second conductivity type may be N type. That is, the JFET 10 and the MOSFET 20 may be of a P-channel type.

In each of the above-described embodiments, the semiconductor device in which the JFET 10 and the MOSFET 20 are cascode-connected has been described. However, the semiconductor device may be configured to have only the MOSFET 20 of the trench gate structure without the JFET 10.

In each of the above-described embodiments, the gate layer 13 and the body layer 115 may have the same depth. The configuration in which the electric field intensity is higher on the bottom side of the body layer 115 than on the bottom side of the gate layer 13 can be changed as appropriate. For example, when the bottom of the body layer 115 may be tapered or the width of the body layer 115 may be narrower than the width of the gate layer 13, the electric field strength tends to be higher on the bottom side of the body layer 115 than on the bottom side of the gate layer 13.

In each of the above-described embodiments, the JFET 10 may be configured using a silicon substrate, or may be configured using another compound semiconductor substrate or the like. Similarly, the MOSFET 20 may be configured using a SiC substrate, or may be configured using another compound semiconductor substrate.

In the first and third embodiments, the impurity concentration of the drift layer 212 in the MOSFET 20 may be gradually lowered in a direction from the drain layer 211 toward the channel layer 213 so as to achieve a high breakdown voltage.

The above-described embodiments may be combined with one another as appropriate. For example, the second embodiment and the third embodiment may be combined to configure an inverter using the MOSFET 20 having the SJ structure. The combinations of each embodiment may be further combined.

What is claimed is:

1. A semiconductor device comprising a metal oxide semiconductor field effect transistor (MOSFET) including:
a drift layer of a first conductivity type;
a channel layer of a second conductivity type disposed on the drift layer;
a trench gate structure including a trench penetrating the channel layer and protruding into the drift layer, a gate insulating film disposed on a wall surface of the trench, and a gate electrode disposed on the gate insulating film;
a source layer of the first conductivity type disposed in a surface layer portion of the channel layer so as to be in contact with the trench and having an impurity concentration higher than an impurity concentration of the drift layer;
a drain layer of the first conductivity type disposed on a side of drift layer opposite from the channel layer;
a source electrode electrically connected to the channel layer and the source layer; and
a drain electrode electrically connected to the drain layer, wherein
a portion of the trench protruding into the drift layer is entirely covered with a well layer of the second conductivity type, and
the well layer is connected to the channel layer.

2. The semiconductor device according to claim 1, further comprising
a junction field effect transistor (JFET) including a source electrode, a drain electrode and a gate electrode, wherein
the MOSFET and the JFET are cascode-connected by electrically connecting the source electrode of the JFET and the drain electrode of the MOSFET.

3. The semiconductor device according to claim 1, wherein
an area density ratio of an impurity area density of the well layer to an impurity area density of the drift layer is in a range from 3.0×10⁻⁵ to 2.0×10⁻⁴ inclusive.

4. The semiconductor device according to claim 3, wherein the area density ratio is in a range from 3.0×10⁻⁵ to 4.0×10⁻⁵ inclusive.
